(19) United States
(12) Patent Application Publication
(10) Pub. No.: US 2026/0114216 A1
(43) Pub. Date: Apr. 23, 2026

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Hideki HORTA, Toyama-shi (JP); Takayuki Yamamoto, Toyama-shi (JP); Kaigo Tahara, Toyama-shi (JP); Ryuji Yamamoto, Tokyo (JP); Junpei Tachibana, Tokyo (JP)

(73) Assignee: Kokusai Electric Corporation, Tokyo (JP)

(21) Appl. No.: 19/332,939

(22) Filed: Sep. 18, 2025

(30) Foreign Application Priority Data
Oct. 18, 2024 (JP) 2024-182455

(51) Int. Cl. H01L 21/67; H01L 21/311

(52) U.S. Cl. CPC H10P 72/0421; H10P 50/283

(57) ABSTRACT

A substance on a substrate is removed by performing: (a) supplying a first gas, which is one of an etching gas containing a halogen element and a reactant gas reacting with the etching gas, to a substrate from a first feeder; and (b) supplying a second gas, which is another of the etching gas and the reactant gas and is different from the one of the etching gas and the reactant gas, from a second feeder different from the first feeder to the substrate, while executing (a), so as to adjust a distribution of a partial pressure of a reaction product generated by a reaction between the first gas and the second gas in a plane of the substrate.

### CROSS-REFERENCE TO RELATED APPLICATION

This application is based upon and claims the benefit of priority from Japanese Patent Application No. 2024-182455, filed on Oct. 18, 2024, the entire contents of which are incorporated herein by reference.

### FIELD

The present disclosure relates to a method of processing a substrate, a method of manufacturing a semiconductor device, a recording medium, and a substrate processing apparatus.

### DESCRIPTION OF THE RELATED ART

As a step in a process of manufacturing a semiconductor device, a process of removing a substance on a substrate may be performed.

### SUMMARY

The present disclosure provides a technique capable of precisely removing a substance from a substrate.

According to an embodiment of the present disclosure, there are performed:
removing a substance on a substrate by performing:
(a) supplying a first gas, which is one of an etching gas containing a halogen element and a reactant gas reacting with the etching gas, to the substrate from a first feeder; and
(b) supplying a second gas, which is another of the etching gas and the reactant gas and is different from the one of the etching gas and the reactant gas, from a second feeder different from the first feeder to the substrate, while executing (a), so as to adjust a distribution of a partial pressure of a reaction product generated by a reaction between the first gas and the second gas in a plane of the substrate.

### BRIEF DESCRIPTION OF THE DRAWINGS

FIG. 1 is a schematic configuration diagram of a vertical processing furnace in a processing apparatus suitably used in one embodiment of the present disclosure, illustrating a longitudinal sectional view of a processing furnace portion.

FIG. 2 is a schematic configuration diagram of the vertical processing furnace in the processing apparatus suitably used in one embodiment of the present disclosure, illustrating a cross-sectional view of the processing furnace portion taken along line A-A of FIG. 1.

FIG. 3 is a schematic configuration diagram of a controller of the processing apparatus suitably used in one embodiment of the present disclosure, illustrating a control system of a controller in a block diagram.

FIG. 4A is a schematic diagram illustrating a flow of gas with respect to a substrate according to one embodiment of the present disclosure. FIGS. 4B to 4D are schematic diagrams each illustrating a flow of gas with respect to a substrate in Modified Example 4 of one embodiment of the present disclosure.

FIG. 5 is a schematic diagram illustrating a flow of gas with respect to a substrate in Modified Example 4 of one embodiment of the present disclosure.

FIGS. 6A to 6E are schematic diagrams illustrating flows of first and second gases with respect to a substrate in Modified Example 6 of one embodiment of the present disclosure, respectively.

FIGS. 7A to 7F are schematic diagrams illustrating flows of first and second gases with respect to a substrate in Modified Example 6 of one embodiment of the present disclosure, respectively.

### DETAILED DESCRIPTION

### Embodiments of Present Disclosure

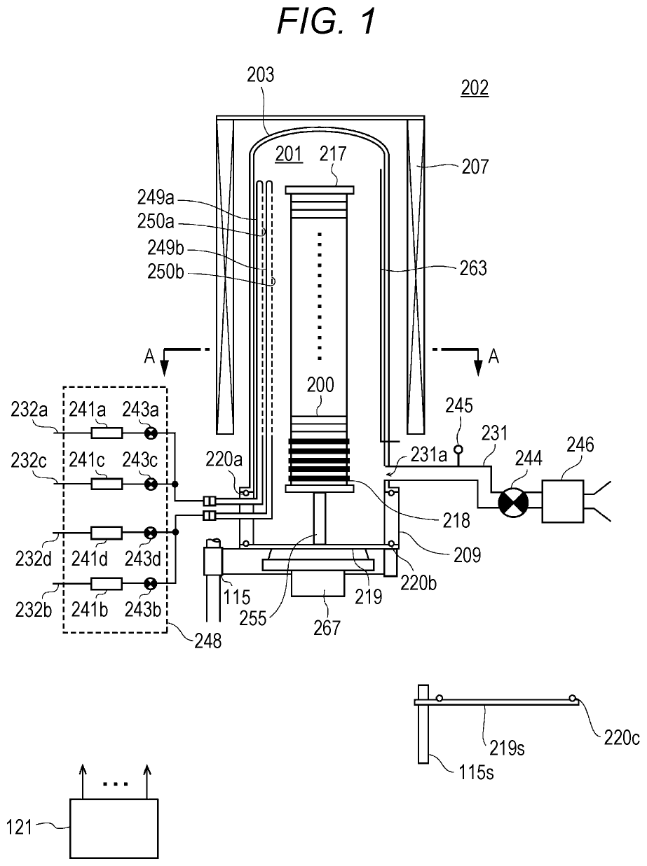

An embodiment of the present disclosure will be hereinafter described mainly with reference to FIGS. 1 to 3 and 4A. The drawings used in the following description are all schematic, and a dimensional relationship between elements, a ratio between elements and the like illustrated in the drawings do not necessarily coincide with actual ones. Between a plurality of drawings, the dimensional relationship between the elements and the ratio between the elements do not necessarily coincide with each other.

### (1) Configuration of Processing Apparatus

As illustrated in FIG. 1, a processing furnace 202 of a processing apparatus includes a heater 207 serving as a temperature regulator (heater). The heater 207 has a cylindrical shape and is supported by a holding plate to be vertically installed. The heater 207 also functions as an activating mechanism (exciter) that thermally activates (excites) a gas.

Inside the heater 207, a reaction tube 203 is arranged concentrically with the heater 207. The reaction tube 203 is formed of, for example, a heat-resistant material such as quartz (SiO₂) or silicon carbide (SiC), and is formed into a cylindrical shape with an upper end closed and a lower end opened. A manifold 209 is arranged below the reaction tube 203 concentrically with the reaction tube 203. An upper end portion of the manifold 209 engages with a lower end portion of the reaction tube 203 and is configured to support the reaction tube 203. An O-ring 220a serving as a seal member is provided between the manifold 209 and the reaction tube 203. A processing container (reaction container) is formed mainly of the reaction tube 203 and the manifold 209. A process chamber 201 is formed in a cylinder hollow portion of the processing container. The process chamber 201 is configured to be able to accommodate a wafer 200 serving as a substrate. The wafer 200 is processed in the process chamber 201.

In the process chamber 201, nozzles 249a and 249b serving, respectively, as first and second feeders are provided, in which the nozzles 249a and 249b penetrate through the side wall of the manifold 209. The nozzles 249a and 249b are also referred to as first and second nozzles, respectively. The nozzles 249a and 249b are each formed of, for example, a heat-resistant material such as quartz or SiC. The nozzles 249a and 249b have, respectively, gas supply pipes 232a and 232b connected thereto. The nozzles 249a and 249b are different nozzles, and are disposed adjacent to each other.

The gas supply pipe 232a is provided with a mass flow controller (MFC) 241a serving as a flow rate controller and a valve 243a serving as an on/off valve in the order from the upstream side of a gas flow. The gas supply pipe 232b is provided with a mass flow controller (MFC) 241b serving as a flow rate controller and a valve 243b serving as an on/off valve in the order from the upstream side of a gas flow. A gas supply pipe 232c is connected to the downstream side of the valve 243a of the gas supply pipe 232a. A gas supply pipe 232d is connected to the downstream side of the valve 243b of the gas supply pipe 232b. The gas supply pipe 232c is provided with an MFC 241c and a valve 243c in the order from the upstream side of a gas flow. The gas supply pipe 232d is provided with an MFC 241d and a valve 243d in the order from the upstream side of a gas flow.

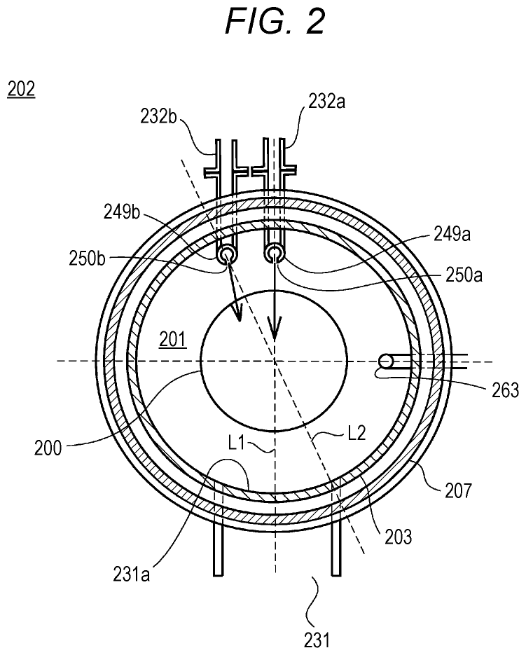

As illustrated in FIG. 2, the space between the inner wall of the reaction tube 203 and a wafer 200 is provided with the nozzles 249a and 249b each extending upward in the direction of an array of wafers 200 along the inner wall of the reaction tube 203 from the lower portion to upper portion of the inner wall. That is, the nozzles 249a and 249b are each provided, in a lateral region horizontally surrounding a wafer array region in which wafers 200 are arrayed, along the wafer array region. In a plan view, the nozzle 249a is disposed so as to be opposed to an exhaust port 231a to be described later across the center of the wafer 200 loaded into the process chamber 201. The nozzle 249b is provided adjacent to the nozzle 249a, that is, at a position substantially facing the exhaust port 231a with the wafer 200 accommodated in the process chamber 201 interposed therebetween. Gas supply holes 250a and 250b for supplying gas from the outer peripheral direction of the wafer 200 into the surface of the wafer 200 are provided on side surfaces of the nozzles 249a and 249b, respectively. Such a plurality of gas supply holes 250a and a plurality of gas supply holes 250b are provided ranging from the lower portion to upper portion of the reaction tube 203.

At least one of the gas supply holes 250a and 250b is configured (adjusted) to supply the gas from an outer edge of the wafer 200 toward the inside of the plane of the wafer 200.

Here, the gas supply hole 250a is configured to supply the gas in a direction from the outer edge of the wafer 200 toward a central portion of the wafer 200, that is, to supply the gas along a straight line L1 passing through the gas supply hole 250a and the center of the wafer 200.

In addition, the gas supply hole 250b is configured to supply the gas along a direction different from the direction from the outer edge of the wafer 200 toward the central portion of the wafer 200, that is, along a direction different from a straight line L2 passing through the gas supply hole 250b and the center of the wafer 200 (a line non-parallel to the straight line L2). Here, the gas supply hole 250b is configured to supply the gas toward the outside of the central portion of the wafer 200 and toward the inside of the outer edge of the wafer 200.

A first gas is supplied from the gas supply pipe 232a into the process chamber 201 via the MFC 241a, the valve 243a, and the nozzle 249a.

The second gas is supplied from the gas supply pipe 232b into the process chamber 201 via the MFC 241b, the valve 243b, and the nozzle 249b.

As the first gas, any one of an etching gas containing a halogen element and a reactant gas reacting with the etching gas can be used. As the second gas, the other gas different from the above-described one (the gas used as the first gas) of these gases can be used. That is, when an etching gas is used as the first gas, a reactant gas can be used as the second gas, and when a reactant gas is used as the first gas, an etching gas can be used as the second gas.

Inert gas is supplied from the gas supply pipe 232c into the process chamber 201 through the MFC 241c, the valve 243c, the gas supply pipe 232a, and the nozzle 249a. Inert gas is supplied from the gas supply pipe 232d into the process chamber 201 through the MFC 241d, the valve 243d, the gas supply pipe 232b, and the nozzle 249b. The inert gas acts as a purge gas, a carrier gas, a diluent gas and the like.

A first gas supply system is configured mainly with the gas supply pipe 232a, the MFC 241a, and the valve 243a. A second gas supply system is configured mainly with the gas supply pipe 232b, the MFC 241b, and the valve 243b. Mainly, with the gas supply pipes 232c and 232d, the MFCs 241c and 241d, and the valves 243c and 243d, an inert gas supply system is achieved.

Any or all of the various supply systems described above may be provided as an integrated supply system 248 including, for example, the valves 243a to 243d and the MFCs 241a to 241d integrated. The integrated supply system 248 is connected to each of the gas supply pipes 232a to 232d, and the operation of supplying various substances (various gases) into the gas supply pipes 232a to 232d, that is, the opening and closing operations of the valves 243a to 243d, the flow rate regulating operations of the MFCs 241a to 241d, and the like are controlled by the controller 121, which will be described later. The integrated supply system 248 is provided as a single integrated unit or a splittable integrated unit such that the integrated supply system 248 can be attached to or detached from the gas supply pipes 232a to 232d per integrated unit. Thus, for example, maintenance, replacement, or addition per integrated unit can be performed to the integrated supply system 248.

The exhaust port 231a from which an atmosphere inside the process chamber 201 is discharged is formed in a lower portion of a side wall of the reaction tube 203. As illustrated in FIG. 2, in plan view, the exhaust port 231a is located opposite (facing) the nozzles 249a and 249b (gas supply holes 250a and 250b) across the wafer 200. The exhaust port 231a may be provided along the side wall of the reaction tube 203 from the lower portion toward the upper portion, that is, along the wafer arrangement region. An exhaust pipe 231 is connected to the exhaust port 231a. A vacuum pump 246 serving as a vacuum-exhaust device is connected to the exhaust pipe 231 via a pressure sensor 245 serving as a pressure detector that detects a pressure in the process chamber 201 and an auto pressure controller (APC) valve 244 serving as a pressure regulator. The APC valve 244 is configured to be able to perform vacuum exhaust and stop the vacuum exhaust inside the process chamber 201 by opening and closing the valve in a state where the vacuum pump 246 is operated, and to be able to regulate a pressure in the process chamber 201 by regulating the degree of valve opening on the basis of pressure information detected by the pressure sensor 245 in a state where the vacuum pump 246 is operated. An exhaust system is formed mainly of the exhaust pipe 231, the APC valve 244, and the pressure sensor 245. The vacuum pump 246 may be included in the exhaust system.

Below the manifold 209, a seal cap 219 is provided serving as a furnace lid capable of airtightly closing a lower end opening of the manifold 209. An O-ring 220b serving as a seal member that abuts the lower end of the manifold 209 is provided on an upper surface of the seal cap 219. A rotating mechanism 267 that rotates a boat 217 to be described later is arranged below the seal cap 219. A rotating shaft 255 of the rotating mechanism 267 penetrates the seal cap 219 and is connected to the boat 217. The rotating mechanism 267 is configured to rotate the boat 217, thereby rotating the wafer 200. The seal cap 219 is configured to be lifted up and down in a vertical direction by a boat elevator 115 serving as a lifting mechanism disposed outside the reaction tube 203. The boat elevator 115 is configured as a transfer device (transfer mechanism) that lifts the seal cap 219 up and down, thereby loading and unloading (transferring) the wafer 200 into/from the process chamber 201.

Below the manifold 209, a shutter 219s serving as a furnace opening lid capable of airtightly closing the lower end opening of the manifold 209 in a state in which the seal cap 219 is lowered and the boat 217 is unloaded from the inside of the process chamber 201 is provided. An O-ring 220c serving as a seal member that abuts the lower end of the manifold 209 is provided on an upper surface of the shutter 219s. The opening/closing operation of the shutter 219s is controlled by a shutter opening/closing mechanism 115s.

The boat 217 serving as a substrate supporter is configured to support a plurality of, for example, 25 to 200 wafers 200 horizontally, in multiple stages so as to be aligned in the vertical direction with the centers aligned with one another, that is, to arrange at intervals. The boat 217 is formed of, for example, a heat-resistant material such as quartz and SiC. Heat insulating plates 218 formed of a heat-resistant material such as quartz and SiC, for example, are supported in multiple stages in a lower portion of the boat 217.

In the reaction tube 203, provided is a temperature sensor 263 serving as a temperature detector. By regulating a degree of energization to the heater 207 on the basis of temperature information detected by the temperature sensor 263, a desired temperature distribution can be achieved in the process chamber 201. The temperature sensor 263 is provided along the inner wall of the reaction tube 203.

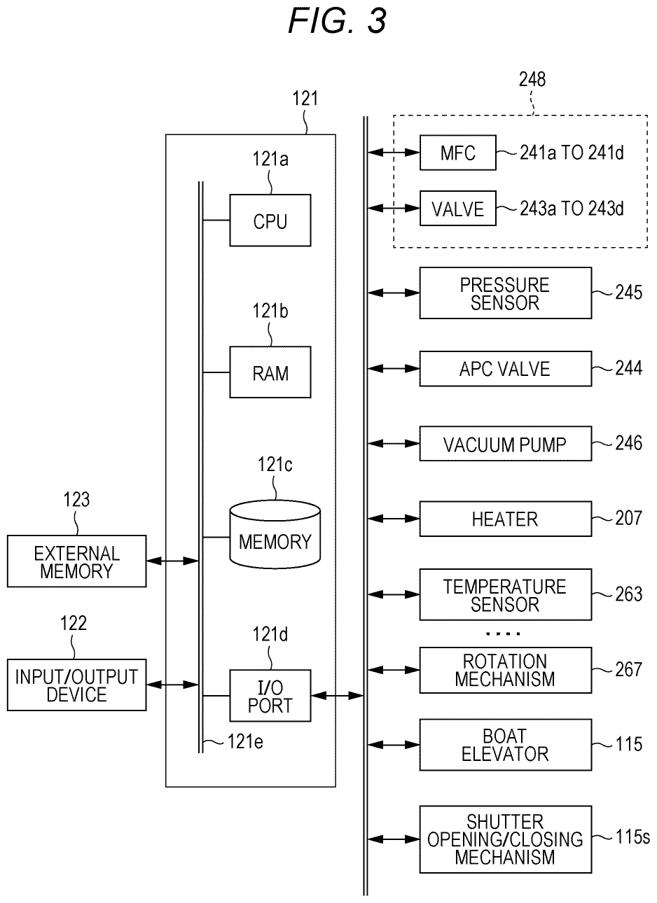

As illustrated in FIG. 3, a controller 121 as a controller (controlling mechanism) is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An input/output device 122 configured as, for example, a touch panel and the like is connected to the controller 121. An external memory 123 can be connected to the controller 121. In addition, a substrate processing apparatus 100 may include a single controller or may include a plurality of controllers. That is, control for performing a processing sequence to be described later may be performed using one controller or a plurality of controllers. A plurality of controllers may be configured as a control system mutually connected by a wired or wireless communication network, and control for performing the processing sequence to be described later may be performed by an entire control system. In a case where the term “controller” is used in this specification, this might include a case where a plurality of controllers is included and a case where a control system formed of a plurality of controllers is included in addition to a case where one controller is included.

The memory 121c includes, for example, a flash memory, a hard disk drive (HDD), a solid state drive (SSD) and the like. In the memory 121c, a control program that controls operation of the substrate processing apparatus 100, a process recipe in which procedures, conditions, and the like of substrate processing described later are described, and the like are readably recorded and stored. The process recipe is a combination formed such that the controller 121 causes the substrate processing apparatus 100 to execute each procedure in substrate processing described later to obtain a predetermined result, and functions as a program. Hereinafter, the process recipe, the control program and the like are collectively and simply referred to as a program (program product). The process recipe is simply referred to as a recipe. In a case where the term “program” is used in the present specification, this may include the recipe alone, the control program alone, or both of them. The RAM 121b is configured as a memory area (work area) in which programs, data and the like read by the CPU 121a are temporarily stored.

The I/O port 121d is connected to, for example, the MFC 241a to 241d, the valves 243a to 243d, the pressure sensor 245, the APC valve 244, the vacuum pump 246, the temperature sensor 263, the heater 207, the rotating mechanism 267, the boat elevator 115, and the shutter opening/closing mechanism 115s described above.

The CPU 121a is configured to be able to read the control program from the memory 121c and execute the same, and read the recipe from the memory 121c in response to an input and the like of an operation command from the input/output device 122. The CPU 121a is configured to be able to control, in accordance with a content of the read recipe, a flow rate regulating operation of various substances (various gases) by the MFCs 241a to 241d, an opening/closing operation of the valves 243a to 243d, a pressure regulating operation by the APC valve 244 based on an opening/closing operation of the APC valve 244 and the pressure sensor 245, start and stop of the vacuum pump 246, a temperature regulating operation of the heater 207 based on the temperature sensor 263, rotation and rotating speed regulating operation of the boat 217 by the rotating mechanism 267, a lifting operation of the boat 217 by the boat elevator 115, an opening/closing operation of the shutter 219s by the shutter opening/closing mechanism 115s and the like.

The controller 121 can be configured by installing the above-described program recorded and stored in the external memory 123 into the computer. Examples of the external memory 123 include, for example, a magnetic disk such as an HDD, an optical disk such as a CD, a semiconductor memory such as a USB memory, an SSD and the like. The memory 121c and the external memory 123 are configured as computer-readable recording media. Hereinafter, they are collectively and simply referred to as recording media. In a case where the term “recording medium” is used in this specification, this might include the memory 121c alone, the external memory 123 alone, or both of them. In addition, the program may be provided to the computer by using a communication means such as the Internet and a dedicated line without using the external memory 123.

### (2) Processing Step

Using the processing apparatus described above, an example of a method (processing method) of processing the substrate, that is, a processing sequence of removing a substance on the wafer 200 serving as the substrate will be described as a step of the manufacturing process (manufacturing method) of the semiconductor device. In the following description, the controller 121 controls the operation of each unit forming the processing apparatus. The processing apparatus is also referred to as a substrate processing apparatus, an etching processing apparatus, or an etching apparatus. The processing method is also referred to as a substrate processing method, an etching processing method, or an etching method.

In the processing sequence in the present embodiment,
(a) step A of supplying a first gas, which is one of an etching gas containing a halogen element and a reactant gas reacting with the etching gas, to the wafer 200 from a nozzle 249a serving as a first feeder; and
(b) step B of supplying a second gas, which is the other of the etching gas and the reactant gas, from a nozzle 249b serving as a second feeder different from the first feeder to the wafer 200, while executing the step A, so as to adjust a distribution (hereinafter also referred to as substrate in-plane distribution of partial pressure) of a partial pressure of a reaction product generated by a reaction between the first gas and the second gas in a plane of the wafer 200,
are performed to remove a substance on the substrate.

In the processing sequence in the present embodiment,
in step B, a case where the distribution of the partial pressure of the reaction product in the plane of the wafer 200 is adjusted by adjusting at least one of the supply flow rate of the second gas or the supply direction of the second gas will be described.

Here, as an example, a case where at least the supply direction of the second gas is adjusted in step B will be described. Specifically, in step B, a case where the first gas is supplied in a direction toward the central portion of the wafer 200 and the second gas is supplied in a direction different from the direction toward the central portion of the wafer 200 will be described.

In the processing sequence in the present embodiment, unless otherwise specified, a case where the first gas is a reactant gas and the second gas is an etching gas will be described as an example. However, the etching gas can be used as the first gas, and the reactant gas can be used as the second gas.

The term “wafer” used in this specification might mean the wafer itself, or a laminate of the wafer and a predetermined layer or film formed on a surface thereof. The term “surface of the wafer” used in this specification might mean the surface of the wafer itself or a surface of a predetermined layer and the like formed on the wafer. The expression “forming a predetermined layer on the surface of the wafer” in this specification might mean that a predetermined layer is directly formed on the surface of the wafer itself or that a predetermined layer is formed on the layer and the like formed on the wafer. In a case where the term “substrate” is used in this specification, this is a synonym of the term “wafer”.

### Wafer Charge and Boat Load

When a plurality of wafers 200 is loaded on the boat 217, the shutter opening/closing mechanism 115s moves the shutter 219s, and the lower end opening of the manifold 209 is opened. Thereafter, as illustrated in FIG. 1, the boat 217 supporting the plurality of wafers 200 is lifted up by the boat elevator 115 and is loaded into the process chamber 201. In this manner, the wafers 200 are prepared in the process chamber 201.

A substance to be etched in an etching process to be described later is formed on the surface of the wafers 200 loaded in the boat 217. This substance includes an oxygen (O) free substance. Examples of the substance include an epitaxial silicon (Si) film, an amorphous Si film, a polysilicon film, a silicon nitride film (SiN film), and a metal-containing film. Here, examples of the metal-containing film include films containing metal elements such as titanium (Ti), zirconium (Zr), hafnium (Hf), tantalum (Ta), niobium (Nb), aluminum (Al), molybdenum (Mo), tungsten (W), silicon (Si), and germanium (Ge), and single films of these metal elements.

### Pressure Regulation and Temperature Regulation

After the boat load is finished, the inside of the process chamber 201 is vacuum-exhausted (decompression-exhausted) by the vacuum pump 246 so as to achieve a desired pressure (vacuum degree). At that time, the pressure in the process chamber 201 is measured by the pressure sensor 245, and the APC valve 244 is feedback-controlled on the basis of information of the measured pressure. The heater 207 heats in such a manner that temperature of the wafer 200 in the process chamber 201 reaches desired processing temperature. At that time, on the basis of the temperature information detected by the temperature sensor 263, the degree of energization to the heater 207 is feedback-controlled in such a manner that the desired temperature distribution is obtained in the process chamber 201. The rotating mechanism 267 starts to rotate the wafer 200. Both the exhaust in the process chamber 201, the heating and rotation of the wafer 200 continue at least until the processing on the wafer 200 is finished.

### Etching Treatment

Thereafter, while executing step A, step B is performed in parallel.

### Step A

In this step, the first gas is supplied to the wafers 200 in the process chamber 201. Here, as an example, a case where a reactant gas that reacts with an etching gas serving as a second gas to be described later is supplied as the first gas will be described.

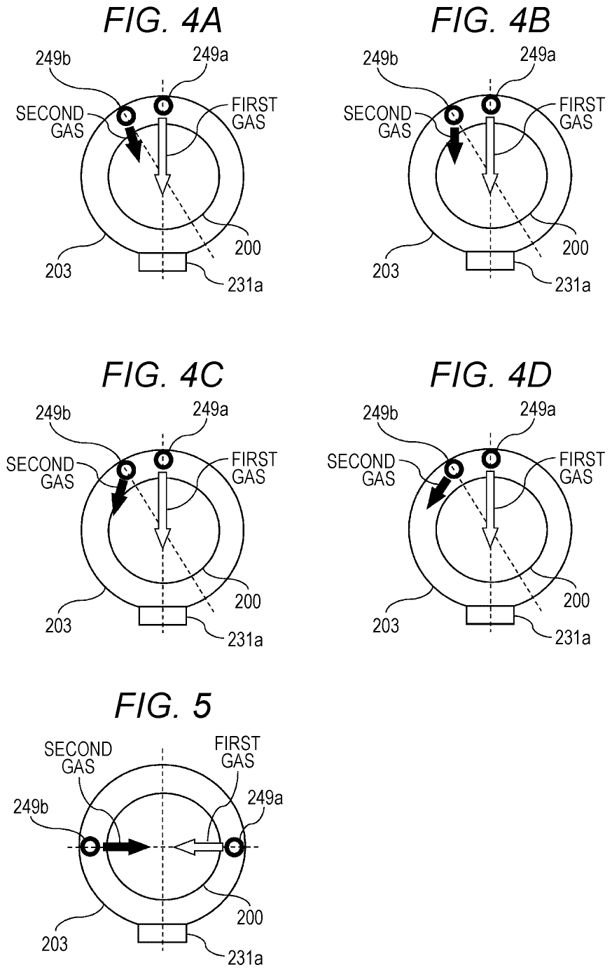

Specifically, the valve 243a is opened to cause the first gas to flow into the gas supply pipe 232a. A flow rate of the first gas is regulated by the MFC 241a, and the first gas is supplied into the process chamber 201 via the nozzle 249a and exhausted from the exhaust port 231a. At this time, the first gas is supplied (discharged) from the outer edge of the wafer 200 toward the inside of the plane of the wafer 200 (first gas supply). Specifically, the first gas is supplied (discharged) in a direction from the outer edge of the wafer 200 toward the central portion of the wafer 200 (for example, a direction along the straight line L1) (see FIG. 4A). In this case, the valves 243b and 243c may be opened to supply inert gases into the process chamber 201 through the nozzles 249a and 249b, respectively.

### Step B

In this step, the second gas is supplied to the wafers 200 in the process chamber 201. Here, as an example, a case where an etching gas containing a halogen element is supplied as the second gas will be described.

Specifically, the valve 243b is opened to cause the second gas to flow into the gas supply pipe 232b. A flow rate of the second gas is regulated by the MFC 241b, and the second gas is supplied into the process chamber 201 via the nozzle 249b and exhausted from the exhaust port 231a. At this time, the second gas is supplied (discharged) from the outer edge of the wafer 200 toward the inside of the plane of the wafer 200 (second gas supply). Specifically, the gas is supplied (discharged) in a direction (for example, a direction different from the direction along the straight line L2) different from the direction from the outer edge of the wafer 200 toward the central portion of the wafer 200, for example, in a direction toward the outer edge side of the wafer 200 (that is, a direction away from the supply direction of the first gas) with respect to the direction from the outer edge of the wafer 200 toward the central portion of the wafer 200 (see FIG. 4A).

The reactant gas is a gas that reacts with the etching gas. The gas that reacts with the etching gas is a gas having an element that reacts with a halogen element contained in the etching gas. Examples of the halogen element include chlorine (Cl), fluorine (F), bromine (Br), and iodine (I). As the reactant gas, for example, a gas containing hydrogen (H), deuterium (D), or oxygen (O) can be used. As the reactant gas, for example, a single gas of each of H, D, or O (that is, a gas composed of a single substance) such as H₂ gas, D₂ gas, O₂ gas, or ozone (O₃) gas can be used. As the reactant gas, for example, a compound gas composed of H and elements other than H, such as an ammonia (NH₃) gas, a phosphine (PH₃) gas, and a monoborane (BH₃) gas, can be used. In addition, as the reactant gas, for example, a compound gas composed of an O element and another element other than the O element, such as a nitrogen monoxide (NO) gas, a carbon monoxide (CO) gas, or a carbon dioxide (CO₂) gas, can be used. Among them, it is preferable to use each single gas of H, D, or O as the reactant gas. Among them, it is preferable to use a gas not containing a halogen element (halogen element-free gas) as the reactant gas. Among them, it is particularly preferable to use a reducing gas such as a gas containing H or D as the reactant gas. As the reactant gas, one or more of these can be used.

The etching gas is a gas containing a halogen element. As the etching gas, for example, a simple substance gas of a halogen element (that is, a gas composed of a halogen element single substance) such as Cl₂ gas, F₂ gas, Br₂ gas, or I₂ gas can be used. Further, as the etching gas, for example, a compound gas composed of halogen elements such as a chlorine monofluoride (ClF) gas, a chlorine trifluoride (ClF₃) gas, and an iodine heptafluoride (IF₇) gas can be used. As the etching gas, for example, a nitrogen (N)-free compound gas composed of a halogen element such as boron trichloride (BCl₃) gas and elements other than the halogen element can be used. As the etching gas, for example, an N-containing compound gas composed of a halogen element such as nitrosyl fluoride (FNO) gas and elements other than the halogen element can be used. One or more of them can be used as the etching gas.

As the inert gas, for example, a rare gas such as a nitrogen (N₂) gas, an argon (Ar) gas, a helium (He) gas, a neon (Ne) gas, or a xenon (Xe) gas can be used. One or more of these gases can be used as the inert gas.

In steps A and B, the processing conditions at the time of supplying the first gas and the second gas are as follows:
Processing temperature: 400 to 700° C., preferably 450 to 550° C.
Processing pressure: 1 to 1330 Pa, preferably 10 to 100 Pa
Processing time: 1 to 6000 seconds, preferably 60 to 1800 seconds
First gas (reactant gas) supply flow rate: 0.1 to 20 slm, preferably 0.5 to 10 slm
Second gas (etching gas) supply flow rate: 0.01 to 2 slm, preferably 0.05 to 1 slm
Inert gas feed rate (per gas supply pipe): 0 to 10 slm, preferably 1 to 5 slm
are exemplified. In this step, it is preferable to supply the first gas and the second gas under a non-plasma condition (under an atmosphere).

Note that, in the present specification, the expression of a numerical range such as “400 to 700° C.” means that a lower limit value and an upper limit value are included in the range. Therefore, for example, “400 to 700° C.” means “equal to or higher than 400° C. and equal to lower than 700° C.”. The same applies to other numerical ranges. In this specification, the processing temperature means the temperature of the wafer 200 or the temperature in the process chamber 201, and the processing pressure means the pressure in the process chamber 201. The processing time means a time in which the processing is continued. In a case where 0 slm is included in the supply flow rate, 0 slm means a case where the substance (gas) is not supplied. The same applies to the following description.

By supplying the second gas so as to mix the first gas and the second gas in the plane of the wafer 200 under the above-described processing conditions, it is possible to generate a reaction product generated by the reaction between the first gas and the second gas in-situ in the plane of the wafer 200. For example, when H₂ gas as a reactant gas is used as the first gas and Cl₂ gas as an etching gas is used as the second gas, hydrogen chloride (HCl) gas can be generated as a reaction product. For example, when an NO gas as a reactant gas is used as the first gas and an F₂ gas as an etching gas is used as the second gas, an FNO gas can be generated as a reaction product.

As described above, since the reaction product is generated in-situ in the plane of the wafer 200, the reaction product is supplied to the surface of the wafer 200 in a highly active state and before the active state is lost as compared with the same type of substance generated in advance outside the process chamber 201, that is, the same type of substance that has been generated for a long time. As described above, in step B, not only the etching gas but also the reaction product in the active state is supplied to the wafer 200.

As described above, by supplying the reaction product to the wafer 200 in addition to the etching gas serving as the second gas, the etching gas and at least a part of the substance on the wafer 200 react with each other, and further, the reaction product and at least another part of the substance on the wafer 200 react with each other, and the substance can be removed from the wafer 200. In other words, the substance on the wafer 200 is not only removed by the reaction between the substance and the etching gas, but also removed by the reaction between the substance and the reaction product.

The type and activity of the reaction product also vary depending on the combination of the etching gas and the reactant gas. Therefore, even when the etching gas and the reaction product react with the substance under the same conditions (for example, partial pressure and temperature), the magnitude relationship between the removal rate of the substance by the reaction with the etching gas (also referred to as an etching rate) and the removal rate of the substance by the reaction with the reaction product may be reversed (changed) according to the combination of the reactant gas and the etching gas. For example, when H₂ gas is used as the reactant gas and Cl₂ gas is used as the etching gas, the removal rate of the substance by the reaction between the substance and the etching gas (Cl₂ gas) is higher than the removal rate of the substance by the reaction between the substance and the reaction product (HCl gas). For example, when NO gas is used as the reactant gas and F₂ gas is used as the etching gas, the removal rate of the substance by the reaction between the substance and the etching gas (F₂ gas) is smaller than the removal rate of the substance by the reaction between the substance and the reaction product (FNO gas).

In addition, as the reactant gas serving as the first gas in the present embodiment, a gas is selected in which the removal rate of the substance by the reaction between the substance and the reactant gas is lower than the removal rate by the etching gas serving as the second gas. Preferably, as the reactant gas serving as the first gas, a gas in which the removal rate of the substance by the reaction between the substance and the reactant gas is smaller than the removal rate by the reaction product is selected. More preferably, as the reactant gas serving as the first gas, a gas in which an etching reaction does not substantially occur between the substance and the reactant gas is selected.

Hereinafter, a specific means (adjustment example) for optimizing the removal amount of the substance on the wafer 200, which is the sum of the removal amount of the substance by the reaction with the second gas (etching gas) (which can also be interpreted as the removal rate, and the same applies hereinafter) and the removal amount of the substance by the reaction with the reaction product, will be described. In addition, the various adjustment examples described below can be used alone or in any combination. In the following various adjustment examples, unless otherwise specified, a case where the reactant gas is used as the first gas and the etching gas is used as the second gas will be described as an example. However, the etching gas can be used as the first gas, and the reactant gas can be used as the second gas.

### Adjustment Example 1

In a case where the substrate in-plane distribution of the partial pressure of the etching gas has a maximum value in a predetermined region A in the plane of the wafer 200 and has a non-uniform distribution (hereinafter, also referred to as a maximum distribution in the region A) that gradually decreases as it goes away from this region, the substrate in-plane distribution of the partial pressure of the reaction product is adjusted so as to have a non-uniform distribution different from the distribution of the partial pressure of the etching gas.

For example, by adjusting the supply direction of the second gas as described above, and further adjusting the supply flow rate of the second gas as needed, the substrate in-plane distribution of the partial pressure of the reaction product becomes a local minimum value in the region A in the plane of the wafer 200, and becomes a non-uniform distribution (hereinafter, such a distribution is also referred to as a minimum distribution in the region A) that gradually increases as the distance from the region A increases. In addition, for example, by adjusting the supply direction of the second gas as described above, and further adjusting the supply flow rate of the second gas as needed, the substrate in-plane distribution of the partial pressure of the reaction product becomes a maximum value in a region B different from the region A in the plane of the wafer 200, and becomes a non-uniform distribution (hereinafter, such a distribution is also referred to as a maximum distribution in the region B) that gradually decreases as the distance from this region increases. At this time, at least one of the supply direction or the supply flow rate of the first gas may be further adjusted so that the substrate in-plane distribution of the partial pressure of the reaction product is a non-uniform distribution as described above.

Here, for example, the region A is an outer peripheral region (that is, a region close to the nozzle 249b for supplying the second gas) of the wafer 200, and the region B is a central region (that is, a region close to the nozzle 249b for supplying the second gas) of the wafer 200.

When the reactant gas is used as the first gas and the etching gas is used as the second gas, the supply direction of at least one of the first gas or the second gas can be adjusted such that the partial pressure of the first gas is larger in the central region serving as the region B than in the outer peripheral region serving as the region A, and the partial pressure of the second gas is larger in the outer peripheral region serving as the region A than in the central region serving as the region B, and further, the supply flow rate of at least one of the first gas or the second gas can be adjusted as needed. By supplying the first gas and the second gas in this manner, when the partial pressure distribution of the etching gas is maximized in the region A, a minimum distribution of the partial pressure of the reaction product in the region A can be obtained, and a maximum distribution of the partial pressure of the reaction product in the region B can be obtained.

On the other hand, when the etching gas is used as the first gas and the reactant gas is used as the second gas, the supply direction of at least one of the first gas or the second gas is adjusted so that the partial pressure of the first gas is larger in the outer peripheral region serving as the region A than in the central region serving as the region B, and the partial pressure of the second gas is larger in the central region serving as the region B than in the outer peripheral region serving as the region A, and further, the supply flow rate of at least one of the first gas or the second gas can be adjusted as needed. By supplying the first gas and the second gas in this manner, when the partial pressure distribution of the etching gas is maximized in the region A, a minimum distribution of the partial pressure of the reaction product in the region A can be obtained, and a maximum distribution of the partial pressure of the reaction product in the region B can be obtained. However, as described above, when the supply direction of the second gas is adjusted to the direction toward the outer edge side with respect to the direction toward the center portion of the wafer 200, it is easier to obtain the distribution of the partial pressures of the first gas, the second gas, and the reaction product as described above by using the etching gas as the second gas.

### Adjustment Example 2

When the substrate in-plane distribution of the partial pressure of the etching gas is a distribution that is minimal in the predetermined region A in the plane of the substrate, the substrate in-plane distribution of the partial pressure of the reaction product is adjusted to be a non-uniform distribution different from this distribution.

For example, by adjusting the supply direction of the second gas as described above, and further adjusting the supply flow rate of the second gas as needed, the substrate in-plane distribution of the partial pressure of the reaction product is set to a distribution that is maximum in the region A in the plane of the wafer 200. In addition, for example, by adjusting the supply direction of the second gas as described above, and further adjusting the supply flow rate of the second gas as needed, the substrate in-plane distribution of the partial pressure of the reaction product is set to a distribution that is minimal in the region B different from the region A in the plane of the wafer 200. At this time, as in Adjustment Example 1, at least one of the supply direction or the supply flow rate of the first gas may be further adjusted so that the substrate in-plane distribution of the partial pressure of the reaction product is a non-uniform distribution as described above.

In the present adjustment example, when the etching gas is used as the first gas and the reactant gas is used as the second gas, the supply direction of at least one of the first gas or the second gas is adjusted such that the partial pressure of the first gas is smaller in the outer peripheral region serving as the region A than in the central region serving as the region B, and the partial pressure of the second gas is larger in the outer peripheral region serving as the region A than in the central region serving as the region B, and further, the supply flow rate of at least one of the first gas or the second gas can be adjusted as needed. By supplying the first gas and the second gas in this manner, when the partial pressure distribution of the etching gas is minimized in the region A, a maximum distribution of the partial pressure of the reaction product in the region A can be obtained, and a minimum distribution of the partial pressure of the reaction product in the region B can be obtained.

On the other hand, when the reactant gas is used as the first gas and the etching gas is used as the second gas, the supply direction of at least one of the first gas or the second gas is adjusted so that the partial pressure of the first gas is larger in the outer peripheral region serving as the region A than in the central region serving as the region B, and the partial pressure of the second gas is smaller in the outer peripheral region serving as the region A than in the central region serving as the region B, and further, the supply flow rate of at least one of the first gas or the second gas can be adjusted as needed. By supplying the first gas and the second gas in this manner, when the partial pressure distribution of the etching gas is minimized in the region A, a maximum distribution of the partial pressure of the reaction product in the region A can be obtained, and a minimum distribution of the partial pressure of the reaction product in the region B can be obtained. However, as described above, when the supply direction of the second gas is adjusted to the direction toward the outer edge side with respect to the direction toward the center portion of the wafer 200, it is easier to obtain the distribution of the partial pressures of the first gas, the second gas, and the reaction product as described above by using the etching gas as the first gas.

### Adjustment Example 3

When the substrate in-plane distribution of the partial pressure of the reaction product is a distribution that is maximum in the region A, the substrate in-plane distribution of the partial pressure of the etching gas is adjusted so as to be a non-uniform distribution different from this distribution.

For example, by adjusting the supply direction of the second gas as described above, and further adjusting the supply flow rate of the second gas as needed, the substrate in-plane distribution of the partial pressure of the etching gas is minimized in the region A. Further, for example, by adjusting the supply direction of the second gas as described above, and further adjusting the supply flow rate of the second gas as needed, the substrate in-plane distribution of the partial pressure of the etching gas is maximized in the region B different from the region A. At this time, at least one of the supply direction or the supply flow rate of the first gas may be further adjusted so that the substrate in-plane distribution of the partial pressure of the etching gas becomes the non-uniform distribution as described above.

### Adjustment Example 4

When the substrate in-plane distribution of the partial pressure of the reaction product is a distribution that is minimal in the region A, the substrate in-plane distribution of the partial pressure of the etching gas is adjusted so as to be a non-uniform distribution different from this distribution.

For example, by adjusting the supply direction of the second gas as described above, and further adjusting the supply flow rate of the second gas as needed, the substrate in-plane distribution of the partial pressure of the etching gas is maximized in the region A. For example, by adjusting the supply direction of the second gas as described above, and further adjusting the supply flow rate of the second gas as needed, the substrate in-plane distribution of the partial pressure of the etching gas is minimized in the region B different from the region A. At this time, at least one of the supply direction or the supply flow rate of the first gas may be further adjusted so that the substrate in-plane distribution of the partial pressure of the etching gas becomes the non-uniform distribution as described above.

### Adjustment Example 5

In a case where the substrate in-plane distribution of the partial pressure of the etching gas is a uniform distribution having a substantially constant size over the entire area in the plane of the wafer 200, for example, the substrate in-plane distribution of the partial pressure of the reaction product is a uniform distribution similar thereto by adjusting the supply direction of the second gas as described above, and further adjusting the supply flow rate of the second gas as needed.

### Adjustment Example 6

In each of the plurality of regions in the plane of the wafer 200, the removal amount of the substance by the reaction between the substance and the reaction product is made different according to the removal amount of the substance by the reaction between the substance and the etching gas.

For example, in a region where the amount of the substance removed by the reaction with the etching gas is large in the plane of the wafer 200, the partial pressure of the reaction product in the region is reduced and the amount of the substance removed by the reaction with the reaction product is reduced, by adjusting the supply direction of the second gas as described above, and further adjusting the supply flow rate of the second gas as needed. In addition, in a region where the amount of the substance removed by the reaction with the etching gas is small, the partial pressure of the reaction product in the region is increased and the amount of the substance removed by the reaction with the reaction product is increased, by adjusting the supply direction of the second gas as described above, and further adjusting the supply flow rate of the second gas as needed.

### Adjustment Example 7

At least one of the supply direction of the second gas or the supply flow rate of the second gas is adjusted so as to adjust the distribution (hereinafter, also referred to as a substrate in-plane distribution of the partial pressure of the reaction product) of the partial pressure of the reaction product in the plane of the wafer 200.

For example, by adjusting the supply direction of the second gas as described above and further adjusting the supply flow rate of the second gas as needed, the substrate in-plane distribution of the partial pressure of the reaction product is set to a desired distribution. At this time, at least one of the supply direction or the supply flow rate of the first gas may be further adjusted so as to adjust the substrate in-plane distribution of the partial pressure of the reaction product.

### Adjustment Example 8

At least one of the supply direction of the second gas or the supply flow rate of the second gas is adjusted so as to adjust the distribution (hereinafter, also referred to as a substrate in-plane distribution) of the ratio of the partial pressure of the etching gas and the partial pressure of the reaction product in the plane of the wafer 200.

For example, by adjusting the supply direction of the second gas as described above and further adjusting the supply flow rate of the second gas as needed, the substrate in-plane distribution of the ratio between the partial pressure of the etching gas and the partial pressure of the reaction product is set to a desired distribution. At this time, at least one of the supply direction or the supply flow rate of the first gas may be further adjusted so as to adjust the substrate in-plane distribution of the ratio of the partial pressure of the etching gas and the partial pressure of the reaction product. In the present adjustment example, in addition to adjusting the substrate in-plane distribution of the partial pressure of the reaction product as in the adjustment example 7, the substrate in-plane distribution of the ratio between the partial pressure of the etching gas and the partial pressure of the reaction product can be adjusted more accurately by adjusting the substrate in-plane distribution of the partial pressure of the etching gas on the wafer 200.

### Adjustment Example 9

At least one of the distribution of the partial pressure of the reaction product in the plane of the wafer 200 and the distribution of the ratio between the partial pressure of the etching gas and the partial pressure of the reaction product in the plane of the wafer 200 is adjusted so that the removal amount of the substance in the plane of the wafer 200 is uniform.

By adjusting the supply direction of the second gas as described above and further adjusting the supply flow rate of the second gas as needed, at least one of the substrate in-plane distribution of the partial pressure of the reaction product or the substrate in-plane distribution of the ratio of the partial pressure of the etching gas and the partial pressure of the reaction product is set to a distribution in which the removal amount of the substance in the plane of the wafer 200 is uniform.

### After-Purge and Atmospheric Pressure Restoration

After the substance on the wafer 200 is removed, the inert gas serving as the purge gas is supplied from each of the nozzles 249a and 249b into the process chamber 201 and is discharged from the exhaust port 231a. Thus, the interior of the process chamber 201 is purged, and the gas remaining in the process chamber 201 and reaction by-products and the like are removed from the interior of the process chamber 201. Thereafter, the atmosphere inside the process chamber 201 is replaced with the inert gas, and the pressure inside the process chamber 201 is returned to a normal pressure.

### Boat Unload and Wafer Discharge

Thereafter, the seal cap 219 is lowered by the boat elevator 115. Then, the processed wafers 200 are unloaded to the outside of the reaction tube 203 in a state of being supported by the boat 217. After being unloaded to the outside of the reaction tube 203, the processed wafers 200 are carried out from the boat 217.

### (3) Effects by Present Embodiment

According to the present embodiment, one or a plurality of effects described below can be obtained.
(a) The substrate in-plane distribution of the partial pressure of the active reaction product generated by the reaction between the first gas and the second gas, that is, the reaction between the reactant gas and the etching gas is adjusted. Furthermore, in order to perform this adjustment, the substrate in-plane distribution of the partial pressure of the etching gas is also adjusted. Thus, the substrate in-plane distribution of the ratio between the partial pressure of the etching gas and the partial pressure of the reaction product is adjusted, and the removal amount of the substance from the wafer 200, which is the sum of the removal amount of the substance by the reaction with the etching gas (as described above, which can also be interpreted as the removal rate) and the removal amount of the substance by the reaction with the reaction product, is optimized at various places in the plane of the wafer 200, and the removal of the substance from the wafer 200 can be precisely performed.
(b) The second gas is supplied so as to mix the first gas and the second gas in the plane of the wafer 200. Thus, the reaction product is generated in-situ in the plane of the wafer 200, and the substrate in-plane distribution of the partial pressure can be efficiently and effectively adjusted. As a result, it is possible to more precisely remove the substance from the wafer 200.

In addition, by generating the reaction product in the plane of the wafer 200, particularly on the region where the etching reaction between the reaction product and the substance occurs, the reaction product in an active state immediately after the generation can be delivered to the region in the plane of the wafer 200, and the removal efficiency of the substance from the wafer 200 can be enhanced.
(c) At least one of the first gas or the second gas is supplied from the outer edge of the wafer 200 toward the inside of the plane of the wafer 200. Thus, the adjustment of the substrate in-plane distribution of the partial pressure of the reaction product can be efficiently and effectively performed over the entire area in the plane of the wafer 200, and the removal of the substance from the wafer 200 can be more precisely performed. In addition, even in a state where the plurality of wafers 200 is supported in multiple stages, the first gas and the second gas can be similarly supplied to each of the wafers 200.
(d) When the substrate in-plane distribution of the partial pressure of the reaction product is non-uniform, the substrate in-plane distribution of the partial pressure of the etching gas is set to a non-uniform distribution different from the substrate in-plane distribution of the partial pressure of the reaction product so as to complement the non-uniform distribution. Thus, it is possible to precisely remove the substance from the wafer 200.
(e) When the substrate in-plane distribution of the partial pressure of the etching gas is non-uniform, the substrate in-plane distribution of the partial pressure of the reaction product is set to a non-uniform distribution different from the substrate in-plane distribution of the partial pressure of the etching gas so as to complement the non-uniform distribution. Thus, it is possible to precisely remove the substance from the wafer 200.
(f) The substance on the wafer 200 is removed by the reaction between the substance and the etching gas and removed by the reaction between the substance and the reaction product. In this case, the removal amount of the substance from the wafer 200, which is the sum of the removal amount of the substance by the reaction with the etching gas and the removal amount of the substance by the reaction with the reaction product, can be optimized at each place in the plane of the wafer 200, and the substance can be precisely removed from the wafer 200.
(g) In each of the plurality of regions in the plane of the wafer 200, the removal amount of the substance by the reaction with the reaction product is made different according to the removal amount of the substance by the reaction with the etching gas. For example, in the in-plane region of the wafer 200 where the removal amount of the substance by the reaction with the etching gas is large, the removal amount of the substance by the reaction with the reaction product is reduced, and in the region where the removal amount of the substance by the reaction with the etching gas is small, the removal amount of the substance by the reaction with the reaction product is increased. Thus, it is possible to accurately remove the substance from the wafer 200 by, for example, uniformizing the removal amount of the substance removed from the wafer 200, which is the sum of these, at each place in the plane of the wafer 200.
(h) The second gas is supplied to the wafer 200 so as to adjust the substrate in-plane distribution of the partial pressure of the reaction product. Thus, it is possible to more effectively control the removal amount of substance from the wafer 200 as compared with the case of adjusting only the in-plane distribution of the partial pressure of the etching gas on the wafer 200.
(i) The second gas is supplied to the wafer 200 so as to adjust the substrate in-plane distribution of the ratio between the partial pressure of the etching gas and the partial pressure of the reaction product. Thus, it is possible to more precisely remove the substance from the wafer 200 over the entire area in the plane of the wafer 200.

In addition, at least one of the substrate in-plane distribution of the partial pressure of the reaction product or the substrate in-plane distribution of the ratio between the partial pressure of the etching gas and the partial pressure of the reaction product is adjusted. Thus, the removal amount of the substance from the wafer 200 can be effectively controlled at each place in the plane of the wafer 200, and for example, the amount of substance removed from the wafer 200 can be made uniform over the entire area in the plane of the wafer 200.
(j) When the reactant gas is supplied as the first gas and the etching gas is supplied as the second gas, the above-described action can be effectively obtained.
(k) At least one of the supply flow rate of the second gas or the supply direction of the second gas is adjusted. Thus, it is possible to efficiently adjust the substrate in-plane distribution of the partial pressure of the reaction product and to more precisely remove the substance from the wafer 200.

That is, in step B, the first gas is supplied in a direction toward the central portion of the wafer 200, and the second gas is supplied in a direction different from the direction toward the central portion of the wafer 200. Thus, it is possible to adjust the substrate in-plane distribution of the partial pressure of the reaction product, to optimize the removal amount of substance from the wafer 200 at various places in the plane of the wafer 200, and to precisely remove the substance from the wafer 200.

That is, in step B, the first gas and the second gas are supplied so that the partial pressure of the first gas in the central portion of the wafer 200 is larger than the partial pressure of the first gas in an outer peripheral portion of the wafer 200. Thus, it is possible to efficiently adjust the substrate in-plane distribution of the partial pressure of the reaction product and to more precisely remove the substance from the wafer 200.

That is, in step B, the first gas and the second gas are supplied so that the partial pressure of the second gas in the outer peripheral portion of the wafer 200 is larger than the partial pressure of the second gas in the central portion of the wafer 200. Thus, it is possible to efficiently adjust the substrate in-plane distribution of the partial pressure of the reaction product and to more precisely remove the substance from the wafer 200.
(l) In step B, the substance on the wafer 200 can be removed not only by the reaction between the substance and the etching gas but also by the reaction between the substance and the reaction product. Thus, the removal rate of the substance from the wafer 200 can be increased.

In addition, when a gas composed of the H element or the D element, a compound gas composed of the H element and elements other than the H element, or the like is used as the reactant gas, impurities generated on the surface of the wafer 200 can be removed by the reduction action of the reactant gas. Thus, when the etching gas is supplied to the wafer 200, it is possible to create an environment in which etching by the etching gas or the reaction product easily proceeds, and it is possible to increase the removal rate of the substance from the wafer 200.
(m) When the etching gas and the reactant gas are supplied under the non-plasma condition, the above-described action can be effectively obtained. Plasma damage to the wafer 200 can be avoided.
(n) The above-described effects can be similarly obtained even in a case where a predetermined substance is optionally selected from the various etching gases, various reactant gases, and various inert gases described above to be used.

### (4) Modified Examples

The present disclosure can be modified as follows. The following modified examples can be freely combined.

### Modified Example 1

In the above-described embodiment, the case where the supply direction of the second gas is adjusted as described above, and further, the supply flow rate of the second gas is adjusted as needed has been described. However, only the supply flow rate of the second gas may be adjusted without adjusting the supply direction of the second gas.

Also in the present modified example, effects can be obtained similar to those in the above-described embodiment. That is, the substrate in-plane distribution of the partial pressure of the reaction product is adjusted, and the substrate in-plane distribution of the partial pressure of the etching gas is also adjusted in order to perform this adjustment. Thus, the substrate in-plane distribution of the ratio between the partial pressure of the etching gas and the partial pressure of the reaction product can be adjusted, and as a result, the substance can be precisely removed from the wafer 200.

### Modified Example 2

In the above-described embodiment, the case of adjusting the supply direction and the supply flow rate of the second gas has been mainly described, but the supply direction and the supply flow rate of the first gas may be adjusted while adjusting the supply direction and the supply flow rate of the second gas. In addition, the supply direction and the supply flow rate of the first gas may be adjusted without adjusting the supply direction and the supply flow rate of the second gas.

Also in the present modified example, effects can be obtained similar to those in the above-described embodiment. That is, the substrate in-plane distribution of the partial pressure of the reaction product is adjusted, and the substrate in-plane distribution of the partial pressure of the etching gas is also adjusted in order to perform this adjustment. Thus, the substrate in-plane distribution of the ratio between the partial pressure of the etching gas and the partial pressure of the reaction product can be adjusted, and as a result, the substance can be precisely removed from the wafer 200.

### Modified Example 3

As illustrated in FIG. 4B, in step B, the second gas may be supplied in a direction parallel to the supply direction of the first gas in plan view. In addition, as illustrated in FIG. 4C, in step B, the second gas may be supplied toward the outer peripheral side (for example, a direction along a tangent of an outer edge of the wafer 200 through the nozzle 249b) of the wafer 200 in plan view. As illustrated in FIG. 4D, in step B, the second gas may be supplied toward the outside of the outer edge of the wafer 200 in plan view.

Also in the present modified example, effects can be obtained similar to those in the above-described embodiment. That is, it is possible to precisely remove the substance from the wafer 200 by adjusting the substrate in-plane distribution of the partial pressure of the reaction product.

### Modified Example 4

As illustrated in FIG. 5, the nozzle 249a and the nozzle 249b may be provided at positions substantially facing each other with the central portion of the wafer 200 interposed therebetween. The nozzles 249a and 249b may be arranged such that a narrow angle between a straight line passing through the nozzle 249a and the center of the wafer 200 and a straight line passing through the nozzle 249b and the center of the wafer 200 is, for example, 120 to 170°, preferably approximately 180°.

In this case, in step B, it is preferable to supply the first gas in a direction toward the central portion of the wafer 200 and to supply the second gas in a direction toward the central portion of the wafer 200.

In this case, in step B, it is preferable to adjust the flow rate of at least one of the first gas or the second gas so that the partial pressure of the reaction product in the central portion of the wafer 200 is larger than the partial pressure of the reaction product in the outer peripheral portion of the wafer 200.

In addition, in this case, in step B, in order to adjust the position where the partial pressure of the reaction product becomes maximum or the like, an inert gas serving as a carrier gas may be added to at least one of the first gas or the second gas to adjust the balance of the flow velocities of the first gas and the second gas.

According to at least one of these, effects similar to those of the above-described embodiment can be obtained. That is, it is possible to precisely remove the substance from the wafer 200 by adjusting the substrate in-plane distribution of the partial pressure of the reaction product.

### Modified Example 5

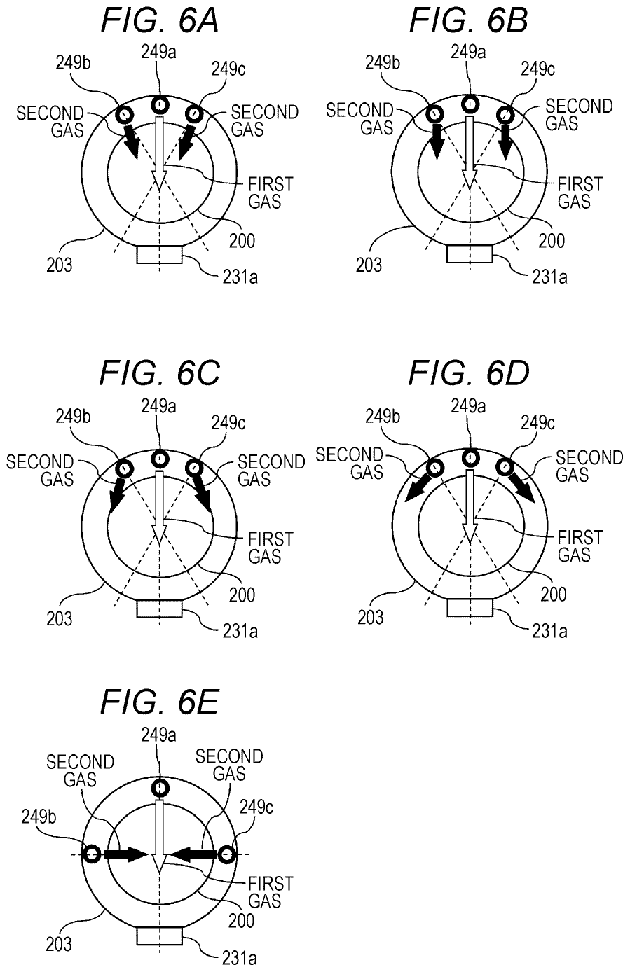

As illustrated in FIG. 6A, a nozzle 249c serving as a third feeder may be further provided on the side opposite to the nozzle 249b across the supply direction of the first gas, that is, across a line passing through the nozzle 249a and the center portion of the wafer 200, and in step B, the second gas may be supplied to the wafer 200 from each of the nozzles 249b and 249c. In addition, the flow rate of the second gas supplied from each of the nozzles 249b and 249c may be the same or different.

In this case, as illustrated in FIGS. 6B to 6D, the second gas may be supplied in a direction parallel to the supply direction of the first gas in plan view, may be supplied toward the outer peripheral side of the wafer 200, or may be supplied toward the outside of the outer edge of the wafer 200.

In this case, as illustrated in FIG. 6E, the nozzle 249b and the nozzle 249c may be provided at positions substantially facing each other across the central portion of the wafer 200. The nozzles 249b and 249c may be arranged such that a narrow angle between a straight line passing through the nozzle 249b and the center of the wafer 200 and a straight line passing through the nozzle 249c and the center of the wafer 200 is, for example, 120 to 170°, preferably approximately 180°.

In this case, as illustrated in FIGS. 6A to 6E, the nozzle 249b and the nozzle 249c may be provided at positions that are line-symmetric with each other across the first gas supply direction. In this case, it is not limited to the embodiment illustrated in FIGS. 6A to 6E, and the nozzle 249b and the nozzle 249c may be provided at positions that are non-linearly symmetrical to each other across the supply direction of the first gas.

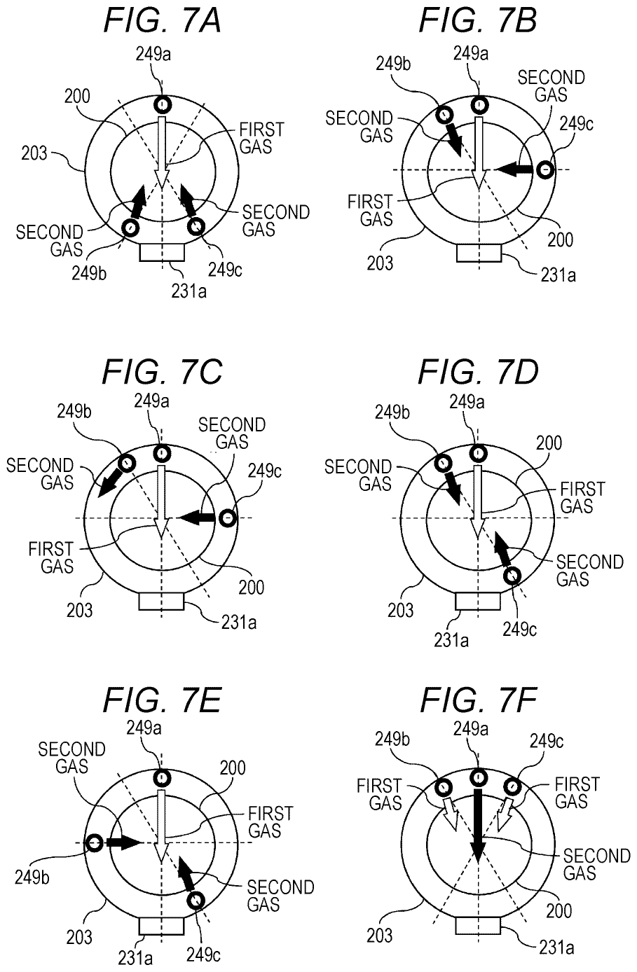

In this case, as illustrated in FIG. 7A, the nozzle 249b and the nozzle 249c may be provided at positions substantially facing the nozzle 249a with the central portion of the wafer 200 interposed therebetween. The nozzle 249a and the nozzle 249b may be arranged such that a narrow angle between a straight line passing through the nozzle 249a and the center of the wafer 200 and a straight line passing through the nozzle 249b and the center of the wafer 200 is, for example, 90 to 170°, preferably equal to or higher than 150°. The arrangement of the nozzles 249a and 249c may be similar.

In this case, as illustrated in FIGS. 7B to 7E, the nozzle 249b and the nozzle 249c may be provided at positions that are non-line-symmetric to each other across the first gas supply direction.

As illustrated in FIG. 7F, the second gas may be supplied from the nozzle 249a, and the first gas may be supplied from the nozzle 249b and the nozzle 249c.

According to at least one of these, effects similar to those of the above-described embodiment can be obtained. That is, it is possible to precisely remove the substance from the wafer 200 by adjusting the substrate in-plane distribution of the partial pressure of the reaction product.

### Other Embodiment of Present Disclosure

The embodiments of the present disclosure have been specifically described above. Note that, the present disclosure is not limited to the embodiments described above, and can be variously modified without departing from the gist thereof.

In the above-described embodiment, an example in which the directions of the openings of the gas supply holes 250a and 250b for supplying the first gas and the second gas are adjusted in advance has been described, but the present disclosure is not limited thereto. For example, when steps A and B are executed, the directions of the openings of the gas supply holes 250a and 250b may be adjusted.

In the above-described embodiment, an example in which a substance to be etched contains an O-free substance has been described, but the present disclosure is not limited thereto. The substance may include, for example, an O-containing substance such as a silicon oxide film (SiO film) or a metal oxide film. Also in this case, the same effects as those of the above-described embodiment can be obtained depending on the types of the etching gas and the reactant gas to be used.

Preferably, a recipe used in each processing is individually prepared according to processing contents and is recorded and stored in the memory 121c via an electric communication line or the external memory 123. When each processing is started, the CPU 121a preferably appropriately selects an appropriate recipe from among a plurality of recipes recorded and stored in the memory 121c according to the processing contents. Therefore, it is possible to perform the various pieces of processing on films with various film types, composition ratios, film qualities, and film thicknesses with excellent reproducibility by using the processing apparatus. It is possible to reduce a burden on an operator, and to quickly start each processing while avoiding an operation error.

The recipe described above is not limited to a newly created recipe, but may be prepared by, for example, changing the existing recipe already installed in the processing apparatus. In a case of changing the recipe, the changed recipe may be installed in the processing apparatus via an electric communication line or a recording medium in which the recipe is recorded. The existing recipe already installed in the processing apparatus may be directly changed by operating the input/output device 122 included in the existing processing apparatus.

In the embodiments and modified examples described above, an example has been described in which the etching processing is performed by using a batch-type processing apparatus that processes a plurality of substrates at a time. The present disclosure is not limited to the embodiments described above, and can be applied to a case of performing the etching processing by using a single wafer type processing apparatus that processes one or more substrates at a time, for example. In the embodiments described above, an example of performing the etching processing using the processing apparatus including a hot wall type of processing furnace has been described. The present disclosure is not limited to the embodiments described above, and can be applied to a case of performing the etching processing by using a processing apparatus including a cold wall type processing furnace.

Even in a case where such processing apparatuses are used, each processing can be performed in accordance with processing procedures and processing conditions similar to those in the embodiments described above and variations, so that effects similar to those in the embodiments described above and variations can be obtained.

The embodiments described above and variations can be used in combination as appropriate. The processing procedures and processing conditions at that time can be similar to the processing procedures and processing conditions in the embodiments described above and variations, for example.

According to the present disclosure, it is possible to precisely remove a substance from a substrate.

What is claimed is:

1. A method of processing a substrate comprising:
removing a substance from the substrate by performing:
(a) supplying a first gas, which is one of an etching gas containing a halogen element or a reactant gas capable of reacting with the etching gas, to a substrate from a first feeder; and
(b) supplying a second gas, which is another of the etching gas or the reactant gas and is different from the one of the etching gas or the reactant gas, from a second feeder different from the first feeder to the substrate, while executing (a), so as to adjust a distribution of a partial pressure of a reaction product generated by a reaction between the first gas and the second gas in a plane of the substrate.

2. The method according to claim 1, wherein in (b), the second gas is supplied so as to mix the first gas and the second gas in the plane of the substrate.

3. The method according to claim 1, wherein in (b), a distribution of a partial pressure of the etching gas in the plane of the substrate is set to a non-uniform distribution.

4. The method according to claim 1, wherein in (b), the distribution of the partial pressure of the reaction product in the plane of the substrate is set to a non-uniform distribution.

5. The method according to claim 1, wherein the substance is not only removed by a reaction between the substance and the etching gas, but also removed by a reaction between the substance and the reaction product.

6. The method according to claim 1, wherein in each of a plurality of regions in the plane of the substrate, an amount of removal of the substance by a reaction between the substance and the reaction product is made different according to an amount of removal of the substance by a reaction between the substance and the etching gas.

7. The method according to claim 1, wherein in (b), the second gas is supplied to the substrate so as to adjust the distribution of the partial pressure of the reaction product in the plane of the substrate.

8. The method according to claim 7, wherein in (b), the distribution of the partial pressure of the reaction product in the plane of the substrate is adjusted by adjusting at least one of a supply flow rate of the second gas or a supply direction of the second gas.

9. The method according to claim 1, wherein in (b), the second gas is supplied to the substrate so as to adjust a distribution of a ratio of a partial pressure of the etching gas and the partial pressure of the reaction product in a plane of the substrate.

10. The method according to claim 9, wherein in (b), the distribution of the ratio of the partial pressure of the etching gas to the partial pressure of the reaction product in the plane of the substrate is adjusted by adjusting at least one of a supply flow rate of the second gas or a supply direction of the second gas.

11. The method according to claim 1, wherein in (b), at least one of a distribution of the partial pressure of the reaction product in the plane of the substrate or a distribution of a ratio between a partial pressure of the etching gas and the partial pressure of the reaction product in the plane of the substrate is adjusted such that an amount of removal of the substance in the plane of the substrate is uniform.

12. The method according to claim 1, wherein in (b), the distribution of the partial pressure of the reaction product in the plane of the substrate is adjusted by adjusting at least one of a supply flow rate of the second gas or a supply direction of the second gas.

13. The method according to claim 1, wherein in (b), the first gas is supplied in a direction toward a central portion of the substrate, and the second gas is supplied in a direction different from the direction toward the central portion.

14. The method according to claim 1, wherein
the first feeder and the second feeder are provided at positions substantially facing each other with a central portion of the substrate interposed therebetween, and
in (b), the first gas is supplied in a direction toward a central portion of the substrate, and the second gas is supplied in a direction toward the central portion.

15. The method according to claim 1, wherein
a third feeder is further provided on a side opposite to the second feeder across a supply direction of the first gas, and
in (b), the second gas is supplied to the substrate from the third feeder.

16. The method according to claim 7, wherein the first gas is the reactant gas, and the second gas is the etching gas.

17. The method according to claim 7, wherein the first gas is the etching gas, and the second gas is the reactant gas.

18. A method of manufacturing a semiconductor device comprising the method of processing a substrate of claim 1.

19. A non-transitory computer-readable recording medium storing a program that causes, by a computer, a substrate processing apparatus to perform a process comprising:
removing a substance on the substrate by performing:
(a) supplying a first gas, which is one of an etching gas containing a halogen element or a reactant gas capable of reacting with the etching gas, to a substrate from a first feeder; and
(b) supplying a second gas, which is another of the etching gas or the reactant gas and is different from the one of the etching gas or the reactant gas, from a second feeder different from the first feeder to the substrate, while executing (a), so as to adjust a distribution of a partial pressure of a reaction product generated by a reaction between the first gas and the second gas in a plane of the substrate.

20. A substrate processing apparatus comprising:
a first gas supply system including a first feeder that supplies a first gas, which is one of an etching gas containing a halogen element or a reactant gas capable of reacting with the etching gas, to a substrate;
a second gas supply system including a second feeder that supplies, to a substrate, a second gas, which is another of the etching gas or the reactant gas and is different from the one of the etching gas or the reactant gas; and
a controller configured to be capable of controlling the first gas supply system and the second gas supply system so as to cause the first feeder to execute (a) supplying the first gas to a substrate, and the second feeder to execute (b) supplying the second gas to the substrate, while executing (a), so as to adjust a distribution of a partial pressure of a reaction product generated by a reaction between the first gas and the second gas in a plane of the substrate.
